(19) United States
(12) Patent Application Publication
(10) Pub. No.: US 2009/0179256 A1
(43) Pub. Date: Jul. 16, 2009

(54) MEMORY HAVING SEPARATED CHARGE TRAP SPACERS AND METHOD OF FORMING THE SAME

(76) Inventors: Sung-Bin Lin, Hsin-Chu City (TW); Hwi-Huang Chen, Hsin-Chu City (TW); Ping-Chia Shih, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 12/013,483

(22) Filed: Jan. 14, 2008

(51) Int. Cl. H01L 29/792; H01L 21/336

(52) U.S. Cl. 257/326; 438/287; 257/E29.309; 257/E21.423

(57) ABSTRACT

A silicon-oxide-nitride-oxide-silicon (SONOS) memory and the corresponding forming method are disclosed. The memory includes a plurality of select gate structures arranged in an array, a plurality of charge trap spacers that do not contact each other, and a plurality of word lines. The word lines can directly contact the select gates' surfaces of the select gate structures. All of the select gate structures disposed in one line can share two charge trap spacers, and the two charge trap spacers are disposed on the opposed sidewalls of these select gate structures.

### BACKGROUND OF THE INVENTION

1. Field of the Invention

The present invention relates to a nonvolatile memory and a method of forming the same, and more particularly, to a silicon-oxide-nitride-oxide-silicon (SONOS) memory.

2. Description of the Prior Art

Nonvolatile memories have the advantages of maintaining stored data while the power supply is interrupted, and thus have been widely employed in recent years. According to the bit numbers stored by a single memory cell, nonvolatile memories are divided into single-bit storage nonvolatile memories, including nitride-based non-volatile memories such as some nitride read-only-memory (NROM), traditional metal-oxide-nitride-oxide-silicon (MONOS) memories or traditional silicon-oxide-nitride-oxide-silicon (SONOS) memories, and dual-bit storage nonvolatile memories, such as split program virtual ground (SPVG) SONOS memories, and SPVG MONOS memories. Comparing to the single-bit storage memories, the SPVG SONOS memories and SPVG MONOS memories are capable of storing more data, and thus have gradually become more and more popular in the memory device market.

Please refer to FIG. 1 and FIG. 2. FIG. 1 and FIG. 2 are schematic diagrams of an SPVG SONOS memory 10, where FIG. 1 illustrates the SPVG SONOS memory 10 during a programming operation, and FIG. 2 illustrates the SPVG SONOS memory 10 during an erasing operation. It is appreciated that only a single memory cell is illustrated in FIG. 1 and FIG. 2 for clearly demonstrating the structure and operational theorem of the SPVG SONOS memory 10. As shown in FIG. 1, the SPVG SONOS memory 10 is formed on a P well 12, which includes a select gate 14, and two N buried bit lines, respectively serving as a drain 16 and a source 18, positioned on the opposite sides of the P well 12. The SPVG SONOS memory 10 further includes a gate insulating layer 20 between the select gate 14 and the P well 12, and a cap layer 22 above the select gate 14. In addition, the SPVG SONOS memory 10 further includes a bottom silicon oxide layer 24, a silicon nitride layer 26, and a top silicon oxide layer 28 on the select gate 14 and the P well 12. The silicon nitride layer 26 works as a storage medium for trapping electrons or hot holes. Furthermore, the SPVG SONOS memory 10 has a word line 30 positioned on the top silicon oxide layer 28.

As shown in FIG. 1, the SPVG SONOS memory 10 is programmed by a source-side injection mechanism. The voltage operations are as follows: the world line 30 is applied with a high positive voltage (e.g. 6 to 9V); the select gate 14 is applied with a low positive voltage (e.g. 1V); the source 18 is applied with a positive voltage (e.g. 4.5V); and the P well 12 and the drain 16 are maintained at 0V. Under these voltage operations, electrons that traverse the channel underneath the select gate 14 will be captured and trapped in the silicon nitride layer 26 close to the source 18 (as the arrow marks shown in FIG. 1) to store a bit of data. In addition, under similar inverse voltage operations, electrons can be trapped in the silicon nitride layer 26 close to the drain 16 to store another bit of data.

As shown in FIG. 2, the SPVG SONOS memory 10 is erased by a band-to-band hot hole injection mechanism. The voltage operations are as follows: the world line 30 is applied with a high negative voltage (e.g. −6 to −9V); the source 18 is applied with a positive voltage (e.g. 4.5V); the select gate 14 is maintained at a level lower than the threshold voltage, and the P well 12 and the drain 16 are maintained at 0V. Under these voltage operations, hot holes in the P well 12 will inject to the silicon nitride layer 26 close to the source 18, and neutralize the electrons trapped in the silicon nitride layer 26 during the programming operation. Similarly, the electrons trapped in the silicon nitride layer 26 close to the drain 16 can be neutralized under similar inverse voltage operations.

Please refer to FIG. 3 to FIG. 7. FIG. 3 to FIG. 7 are schematic diagrams illustrating a traditional method of forming an SPVG SONOS memory, where FIG. 3 to FIG. 6 are cross-sectional views of some memory cells, and FIG. 7 is a schematic diagram of the traditional SPVG SONOS memory. As shown in FIG. 3, a semiconductor substrate 100 is provided, and at least a P well 102 is formed in the semiconductor substrate 100. Substantially, a plurality of select gate structures 104 is formed on the P well 102. Each select gate structure 104 from bottom to top includes a gate insulating layer 106, a select gate 108, and a cap layer 110.

As shown in FIG. 4, a material layer (not shown) is deposited on the semiconductor substrate 100 and the select gate structures 104, and an etching back process is next performed on the said material layer to form a plurality of sacrificial spacers 112 alongside each select gate structure 104. Meanwhile, a plurality of openings 114 is formed between any two adjacent sacrificial spacers 112 to expose the P well 102. Afterward, an implantation process is performed via each opening 114 to form a plurality of N doped regions 116, serving as buried bit lines, in the P well 102. In addition, a drive-in process is performed to diffuse the dopants in the N doped regions.

As shown in FIG. 5, the sacrificial spacers 112 alongside each select gate structure 104 are removed. Next, a composite dielectric layer 118 is formed on the P well 102, the select gate structure 104, and the N doped regions 116 for being a storage medium of electrons. The composite dielectric layer 118 is an oxide-nitride-oxide (ONO) tri-layer dielectric including a bottom silicon oxide layer 120, a silicon nitride layer 122, and a top silicon oxide layer 124.

As shown in FIG. 6 and FIG. 7, a conductive layer (not shown) is entirely deposited on the composite dielectric layer 118, and a photolithography and etching process is performed to define a plurality of parallel word lines 126, which are perpendicular to the select gate structures 104, and the traditional SPVG SONOS memory is therefore formed.

Since the traditional tri-layer dielectric is a continuous structure that completely covers the select gate structures, and the cap layers should be formed on the traditional select gate structures, additional interconnections must be fabricated in the traditional method to control the voltages of the select gates. It extra enlarges the layout area of a SPVG SONOS memory, and leads to a complicated manufactory process of forming the SPVG SONOS memory. Furthermore, the fabrication of the sacrificial spacers is needed for the traditional SPVG SONOS memory, and also increases the complexity of the manufactory process. In addition, all the applied voltages of the word lines, the applied voltages of the select gates and the applied voltages of the sources must be controlled simultaneously in the SPVG SONOS memory according to the traditional operation, and all the voltages of the p wells and the voltages of the drains must be maintained at certain voltages, during both the programming operation and the erasing operation. As a result, the operation of the traditional SPVG SONOS memory is troublesome due to the structure of the SPVG SONOS memory.

### SUMMARY OF THE INVENTION

It is therefore a primary objective of the present invention to provide a SONOS memory to overcome the problems of the prior art.

From one aspect of the present invention, a memory having separated charge trap spacers is disclosed. The memory includes a semiconductor substrate, a plurality of select gate structures, a plurality of charge trap spacers, and a plurality of word lines. The semiconductor substrate includes at least a first conductive type well adjacent to a surface the semiconductor substrate, and a plurality of second conductive type doped regions disposed in the first conductive type well. The select gate structures are disposed between the second conductive type doped regions, and arranged in at least one line. Each of the select gate structures includes a gate dielectric layer disposed on the first conductive type well and a gate conductive layer disposed on the gate dielectric layer. The select gate structures do not contact each other. The charge trap spacers are disposed on opposite sidewalls of the select gate structures. The word lines directly contact upper surfaces of the gate conductive layers.

From another aspect of the present invention, a method of forming a memory having separated charge trap spacers is disclosed. First, a semiconductor substrate is provided. The semiconductor substrate includes at least a first conductive type well adjacent to a surface of the semiconductor substrate. Subsequently, a plurality of bar structures, which do not contact each other, is formed. The bar structures are disposed on a surface of the first conductive type well, and each of the bar structures includes a gate dielectric layer disposed on the first conductive type well and a gate conductive layer disposed on the gate dielectric layer. Next, a plurality of charge trap spacers is formed. Two opposite sidewalls of each of the bar structures contact two of the charge trap spacers respectively. Furthermore, an implantation process is performed by utilizing the bar structures and the charge trap spacers as a mask to form a plurality of second conductive type doped regions in the first conductive type well between the bar structures. Next, an inter-gate dielectric layer is formed. The inter-gate dielectric layer is disposed on the second conductive type doped regions. Following that, a conductive layer is formed on the whole semiconductor substrate. The conductive layer directly contacts a surface of the gate conductive layers. Thereafter, the conductive layer and the bar structures are etched so as to turn the conductive layer into a plurality of word lines, which are perpendicular to each of the second conductive type doped regions and do not contact each other, and to turn each of the bar structures into a plurality of select gate structures.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 illustrates the SPVG SONOS memory during a programming operation;

FIG. 2 illustrates the SPVG SONOS memory during an erasing operation;

FIG. 3 to FIG. 7 are schematic diagrams illustrating a traditional method of forming an SPVG SONOS memory;

FIG. 8 to FIG. 15 are schematic diagrams illustrating a method of forming an SPVG SONOS memory according to the first preferred embodiment of the present invention;

FIG. 16 is a schematic exterior diagram of parts of an SPVG SONOS memory according to the second preferred embodiment of the present invention;

FIG. 17 is a schematic exterior diagram of parts of an SPVG SONOS memory according to the third preferred embodiment of the present invention;

FIG. 18 to FIG. 19 are schematic diagrams illustrating a method of forming an SPVG SONOS memory according to the fourth preferred embodiment of the present invention; and

FIG. 20 to FIG. 21 are schematic diagrams illustrating a method of forming an SPVG SONOS memory according to the fifth preferred embodiment of the present invention.

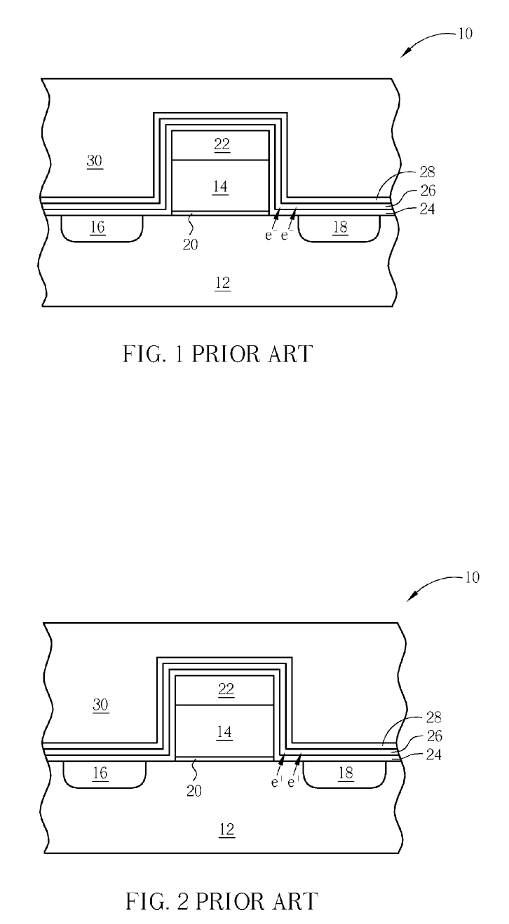

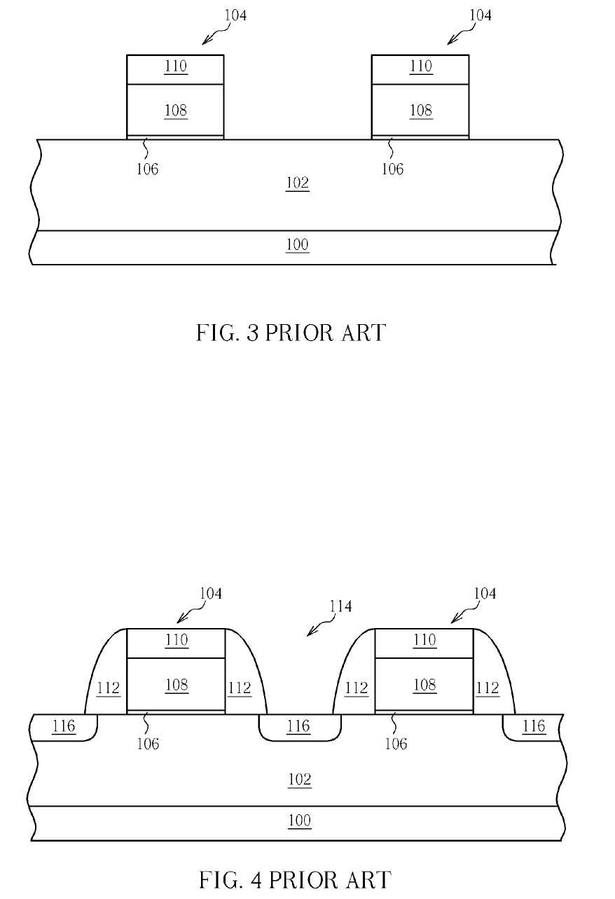

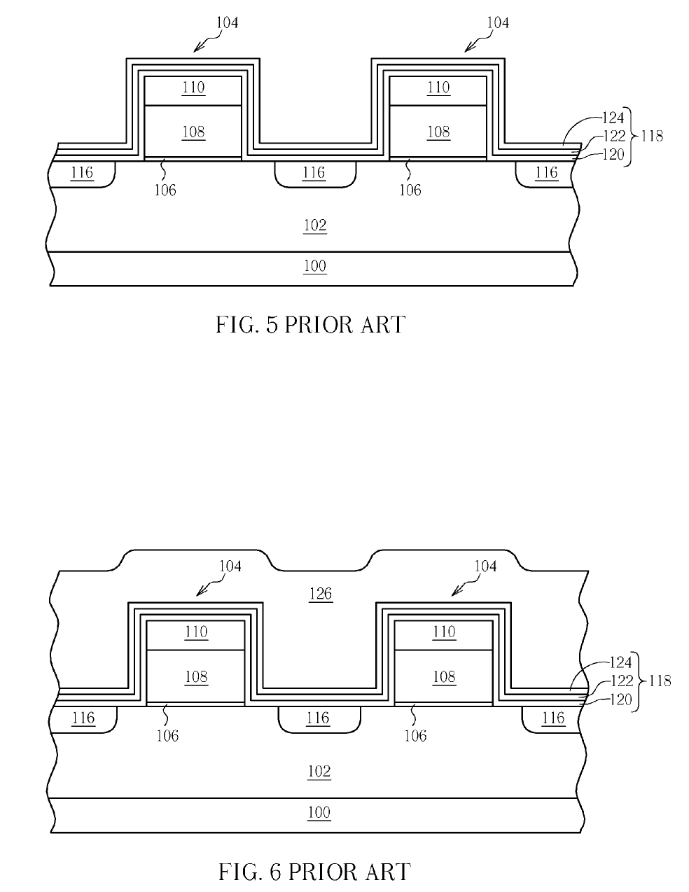

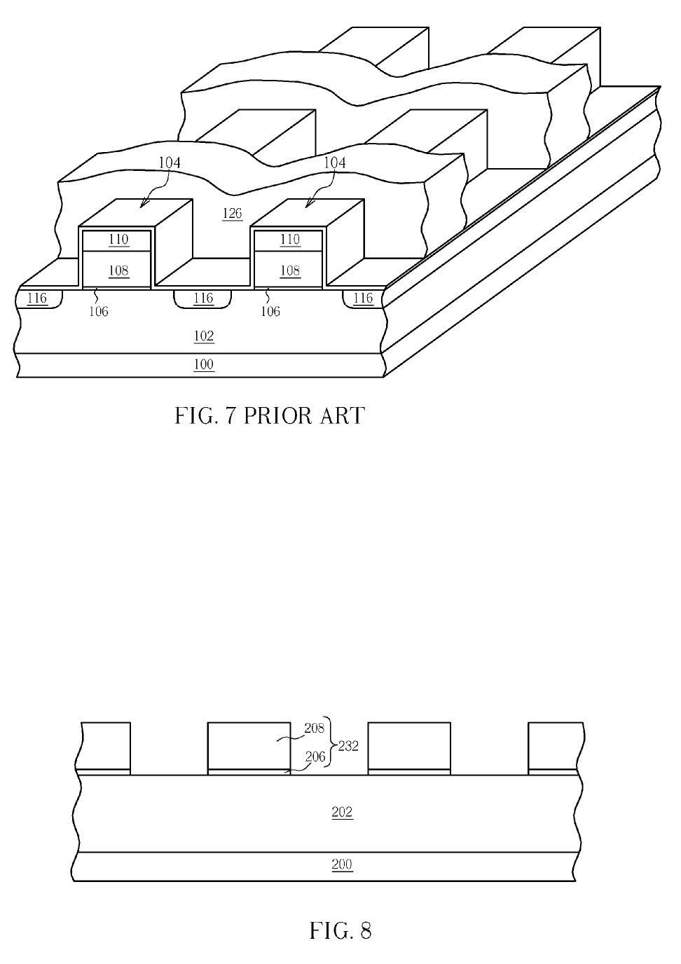

### DETAILED DESCRIPTION

The present invention can be applied to various memory structures, such as SPVG SONOS memories, SPVG MONOS memories, one-time programming memory (OTP), multi-time programming memory (MTP), or embedded one-time programming memory (eOTP).

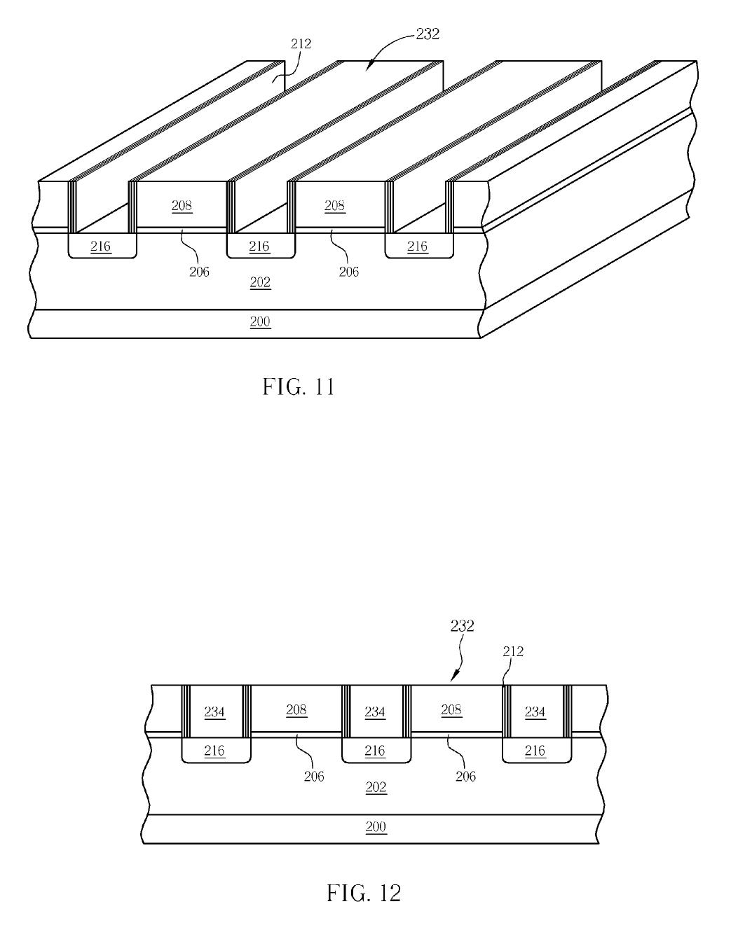

Please refer to FIG. 8 to FIG. 15. FIG. 8 to FIG. 15 are schematic diagrams illustrating a method of forming an SPVG SONOS memory according to the first preferred embodiment of the present invention. It is to be appreciated that for emphasizing the characteristic of the present invention, FIG. 8 to FIG. 10 and FIG. 12 to FIG. 14 are cross-sectional views of parts of memory cells, and FIG. 11 and FIG. 15 are schematic exterior diagrams of parts of an SPVG SONOS memory. It is to be understood that the drawings are not drawn to scale and are served only for illustration purposes. As shown in FIG. 8, a semiconductor substrate 200 is first provided. At least a P well 202 is formed in the semiconductor substrate 200 through a patterned mask (not shown in the drawings) and an ion implantation process. Substantially, a dielectric layer (not shown in the drawings) is formed on the surface of the P well 202 by a thermal oxidization process or a deposition process, and a conductive layer (not shown in the drawings) is deposited on the surface of the dielectric layer. Thereafter, another patterned mask (not shown in the drawings) is formed on the surface of the conductive layer to define positions of bar structures. Next, an etching process is carried out on the said conductive layer and the dielectric layer so as to form a plurality of bar structures 232. Each bar structure 232 from bottom to top includes a gate dielectric layer 206 and a gate conductive layer 208, and serves as a select gate of an SPVG SONOS memory. The gate dielectric layer 206 can include insulating material layers, such as a silicon oxide layer. The gate conductive layer 208 can include conductive materials, such as a polysilicon layer or a metal layer.

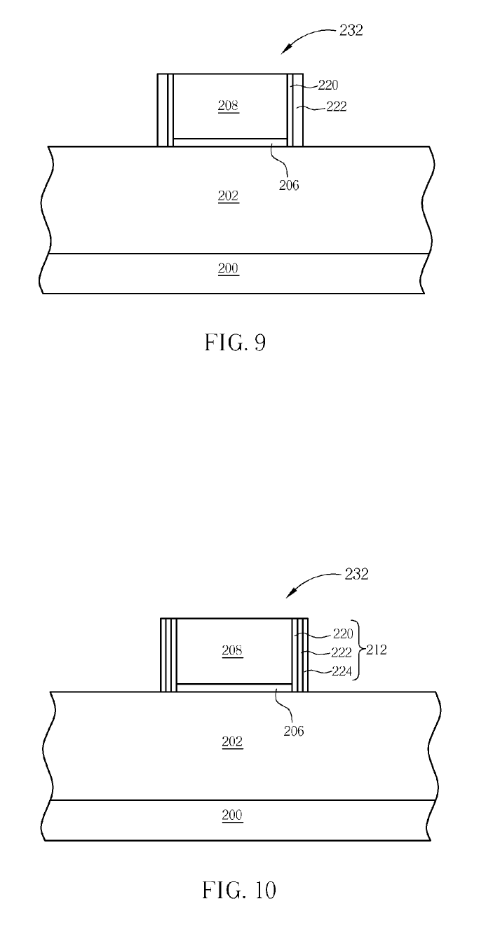

As shown in FIG. 9, a first silicon oxide layer 220 can be generally deposited on the surface of the semiconductor substrate 200 and on the surface of the bar structures 232, and the first silicon oxide layer 220 covers the sidewalls of the bar structures 232. Next, a first silicon nitride layer 222 can be generally deposited on the semiconductor substrate 200, and covers the surface of the first silicon oxide layer 220. Afterward, a first etching back process is performed on the first silicon nitride layer 222 and on the first silicon oxide layer 220. The first etching back process can expose the gate conductive layer 208 of the bar structures 232 and parts of the semiconductor substrate 200 between the bar structures 232. Parts of the first silicon oxide layer 220 and parts of the first silicon nitride layer 222 disposed on sidewalls of the bar structures 232 remain. As shown in FIG. 10, an oxidization process can be carried out on the first silicon nitride layer 222 so that the outer surface of the first silicon nitride layer 222 is oxidized and is turned into a second silicon oxide layer 224. Accordingly, a plurality of charge trap spacers 212 having I-shape structures is formed as storage mediums of electrons. Two opposite sidewalls of each bar structure 232 contact two of the charge trap spacers 212 respectively. It deserves to be mentioned that the charge trap spacers 212 of the present invention can expose the upper surface of the gate conductive layer 208 of each bar structure 232 so the gate conductive layers 208 can directly contact the subsequently formed word lines.

In other embodiments, a second silicon oxide layer (not shown) can be generally deposited on the semiconductor substrate 200, and covers the surface of the first silicon nitride layer 222. Afterward, a second etching back process is performed on the second silicon oxide layer. The second etching back process can expose the gate conductive layer 208 of the bar structures 232 and parts of the semiconductor substrate 200 between the bar structures 232. A second silicon oxide layer 224 disposed on the opposite sidewalls of each bar structure 232 remains. Accordingly, a plurality of charge trap spacers 212 is formed.

In this embodiment, the charge trap spacers 212 can be an oxide-nitride-oxide (ONO) composite structure including the first silicon oxide layer 220, the first silicon nitride layer 222, and the second silicon oxide layer 224. Other examples of the composite structure including an oxide/nitride bi-layer dielectric, a nitride/oxide bi-layer dielectric, an oxide/tantalum oxide bi-layer dielectric (SiO₂/Ta₂O₅), an oxide/tantalum oxide/oxide tri-layer dielectric (SiO₂/Ta₂O₅/SiO₂), an oxide/strontium titanate bi-layer dielectric (SiO₂/SrTiO₃), an oxide/barium strontium titanate bi-layer dielectric (SiO₂/BaSrTiO₂), an oxide/strontium titanate/oxide tri-layer dielectric (SiO₂/SrTiO₃/SiO₂), an oxide/strontium titanate/barium strontium titanate tri-layer dielectric (SiO₂/SrTiO₃/BaSrTiO₂), an oxide/hafnium oxide/oxide tri-layer dielectric (SiO₂/Hf₂O₅/SiO₂), and the like (in each case, the first layer mentioned is the bottom layer while the last layer mentioned is the top layer) can be applied as the storage medium of electrons.

Afterward, as shown in FIG. 11, a self-aligned implantation process is performed by utilizing the bar structures 232 and the charge trap spacers 212 as a mask to form a plurality of N doped regions 216 in the P well 202 between the bar structures 232. The N doped regions 216 can serve as sources/drains and buried bit lines of the memory. In addition, a drive-in process can be alternatively performed to diffuse the dopants in the N doped regions 216. It is to be appreciated that this embodiment illustrates the method of forming an NMOS type SPVG SONOS memory, and therefore P well 202 and N doped regions 216 are formed in the semiconductor substrate 200. If a PMOS type SPVG SONOS memory is to be fabricated, next different dopants must be utilized to form an N well and P doped regions.

It is also to be noted that after the gate conductive layer 208 is formed, a liner oxide layer (not shown) can be alternatively formed as an etching stop layer when forming the charge trap spacers 212. The materials of the charge trap spacers 212 can be adjusted according to the presence or the absence of the liner oxide layer (not shown), so that a better etching selectivity is obtained. In addition, the liner oxide layer (not shown) can also serve as a sacrificial layer to protect the lattice structure of the N doped regions 216 during the implantation process.

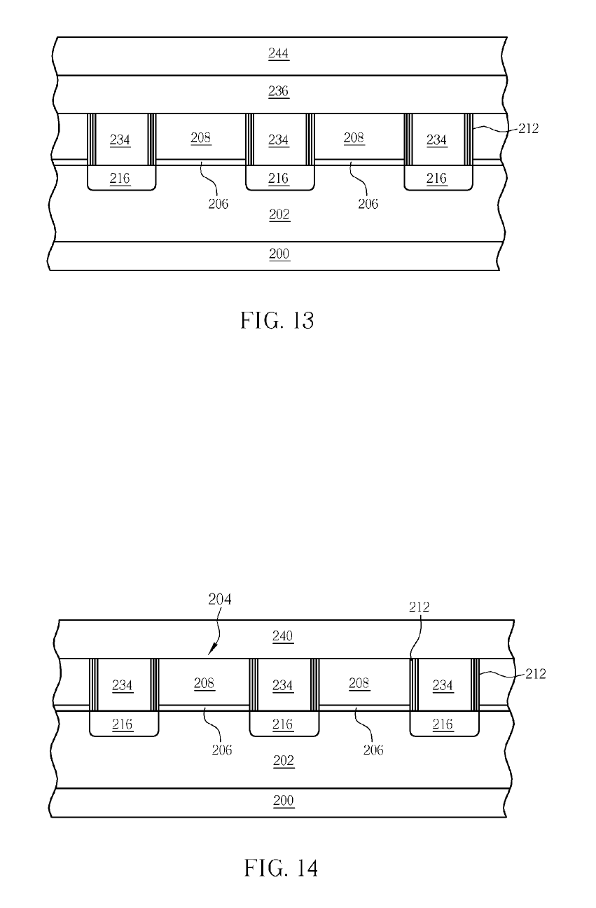

As shown in FIG. 12, a dielectric layer (not shown) is entirely formed on the whole semiconductor substrate 200. The dielectric layer covers the bar structures 232 and the N doped regions 216, and fills up gaps between the bar structures 232. Thereafter, a planarization process, such as an etching back process or a chemical mechanical polishing (CMP) process, can be performed on this dielectric layer until exposing the gate conductive layers 208 of the bar structures 232. Accordingly, an inter-gate dielectric layer 234 is formed on the N doped regions 216.

Following that, as shown in FIG. 13, a conductive layer 236, such as a polysilicon layer, a metal layer, or a polycide, is formed on the whole semiconductor substrate 200. The conductive layer 236 directly contacts the surface of the gate conductive layers 208. Thereafter, a patterned mask 244 disposed on the conductive layer 236 is formed. The patterned mask 244 has a plurality of strip openings (not shown in the drawing), which do not contact each other, and the strip openings are substantially perpendicular to each of the bar structures 232.

As shown in FIG. 14 and FIG. 15, an etching process is performed on the conductive layer 236 and the bar structures 232 by utilizing the patterned mask 244 as an etching mask until each bar structures 236 is turned into a plurality of select gate structures 204, and the conductive layer 236 is turned into a plurality of word lines 240. The word lines 240 are perpendicular to each N doped region 216 and do not contact each other. The etching process can remove parts of the conductive layer 236 that are not covered by the patterned mask 244 and parts of the bar structures 232 that are not covered by the patterned mask 244. Parts of the charge trap spacers 212 that are not covered by the patterned mask 244 remain. Furthermore, the patterned mask 244 can be removed, and an SPVG SONOS memory of this embodiment is therefore fabricated.

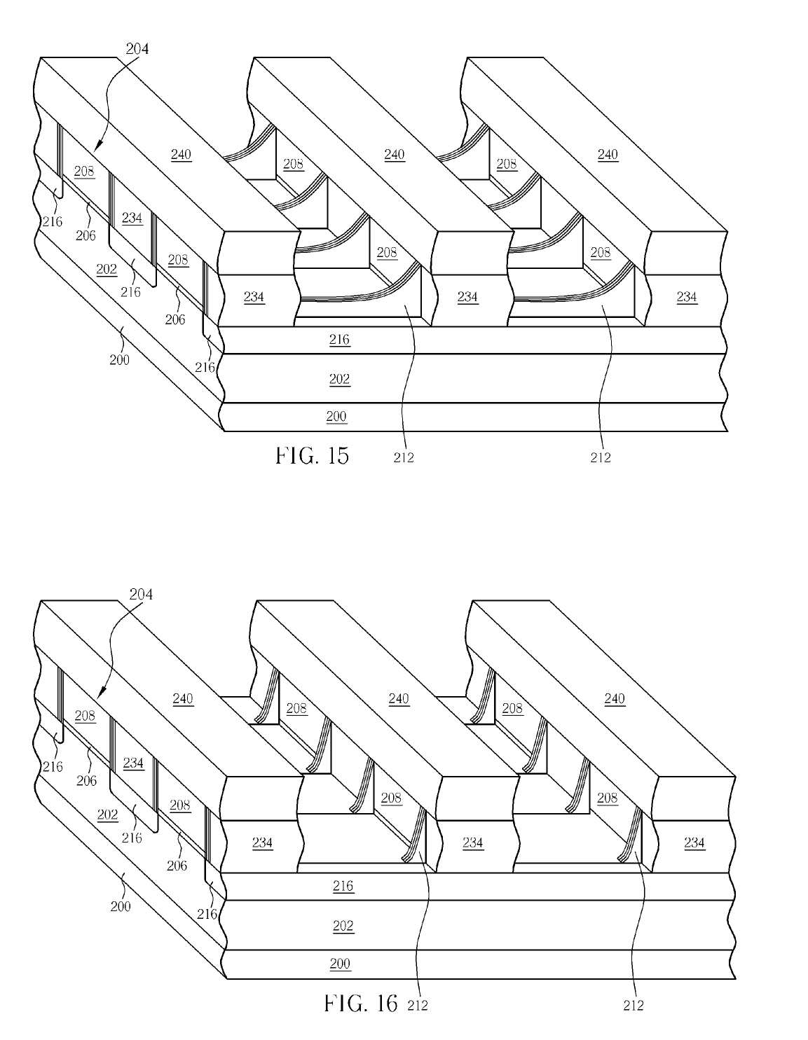

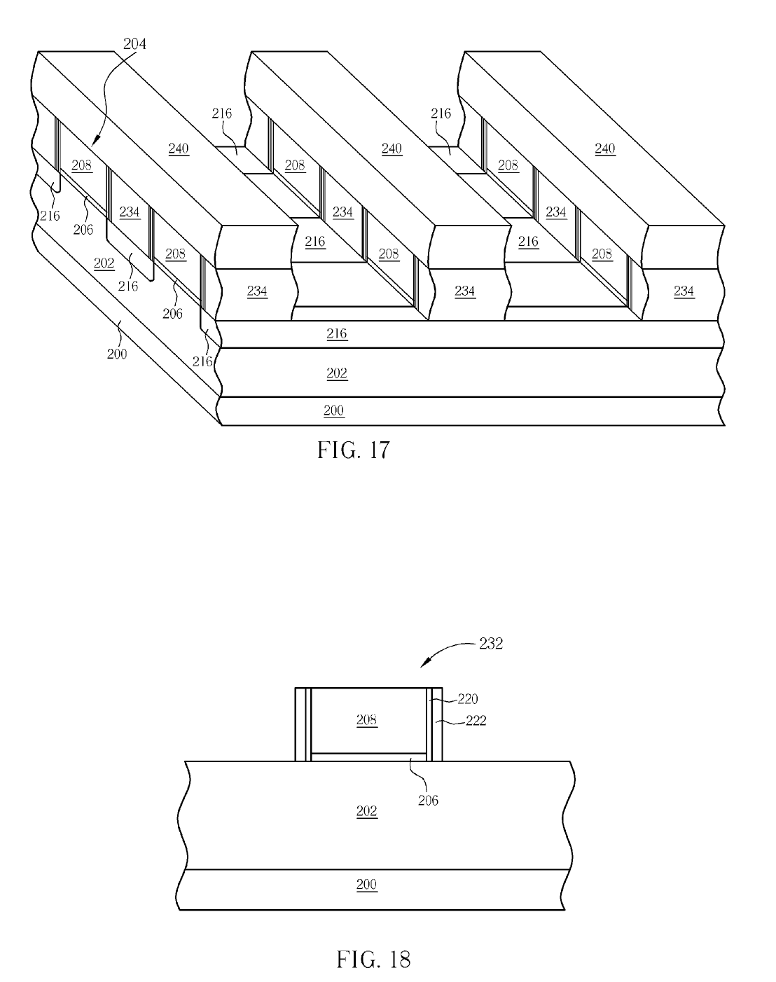

It is appreciate that parts of the semiconductor substrate 200 that are disposed right under the charge trap spacers 212 might also be exposed during the etching process of forming the select gate structures 204, or parts of the charge trap spacers 212, that are not covered by the patterned mask 244, might even be directly removed during the etching process in other embodiments of the present invention. Accordingly, charge trap spacers 212 of one of the select gate structures 204 do not connect with the charge trap spacers 212 of the adjacent select gate structure 204 disposed in the same line with the former select gate structure 204. Please refer to FIG. 16 and FIG. 17. FIG. 16 is a schematic exterior diagram of parts of an SPVG SONOS memory according to the second preferred embodiment of the present invention, and FIG. 17 is a schematic exterior diagram of parts of an SPVG SONOS memory according to the third preferred embodiment of the present invention. As shown in FIG. 16, the etching process exposes parts of the semiconductor substrate 200 that are disposed right under the charge trap spacers 212 so that charge trap spacers 212 of one of the select gate structures 204 do not connect with the charge trap spacers 212 of the adjacent select gate structure 204 disposed in the same line with the former select gate structure 204. As shown in FIG. 16, parts of the charge trap spacers 212 that are not covered by the patterned mask 244 are completely removed.

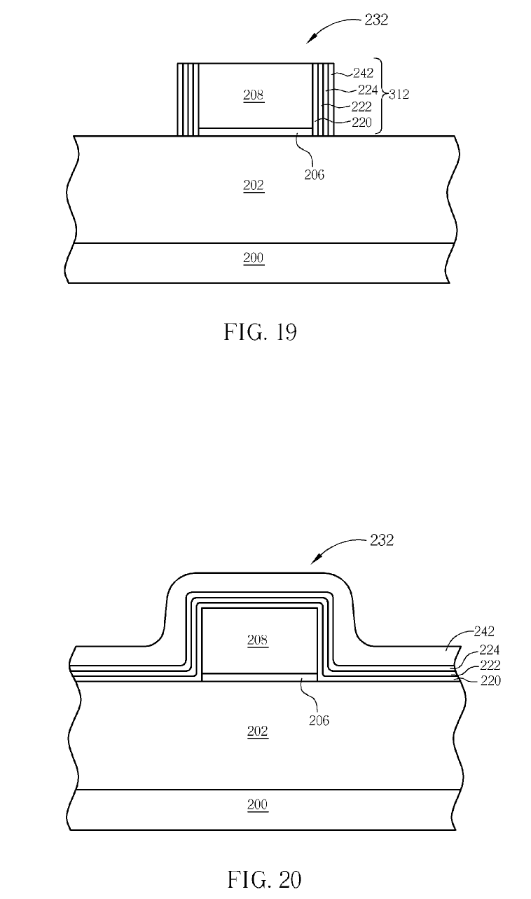

It is noteworthy that the charge trap spacers can be oxide-nitride-oxide-nitride (ONON) composite structures in other embodiments of the present invention, while the charge trap spacers are oxide-nitride-oxide (ONO) composite structures in the first and second preferred embodiments. Please refer to FIG. 18 to FIG. 19. FIG. 18 to FIG. 19 are schematic diagrams illustrating a method of forming an SPVG SONOS memory according to the fourth preferred embodiment of the present invention, where like number numerals designate similar or the same parts, regions or elements. As shown in FIG. 18, a semiconductor substrate 200 is first provided. The semiconductor substrate 200 includes at least a P well 202 therein and a plurality of bar structures 232 thereon. Each bar structure 232 from bottom to top includes a gate dielectric layer 206 and a gate conductive layer 208.

Thereafter, a first silicon oxide layer 220 and a first silicon nitride layer 222 are generally deposited in turn on the surface of the semiconductor substrate 200 and on the surface of the bar structures 232. Afterward, a first etching back process is performed on the first silicon nitride layer 222 and on the first silicon oxide layer 220. The first etching back process can expose the gate conductive layer 208 of the bar structures 232 and parts of the semiconductor substrate 200 between the bar structures 232. Parts of the first silicon oxide layer 220 and parts of the first silicon nitride layer 222 disposed on sidewalls of the bar structures 232 remain.

As shown in FIG. 19, an oxidization process can be carried out on the first silicon nitride layer 222 so that the outer surface of the first silicon nitride layer 222 is oxidized and is turned into a second silicon oxide layer 224. Next, a nitrification process, or a deposition process and an etching process, are performed to form a second nitride layer 242 outside the second silicon oxide layer 224. The second nitride layer 242 covers a surface of the second oxide layer 224, and exposes the gate conductive layer 208 of the bar structures 232 and parts of the semiconductor substrate 200 between the bar structures 232. Accordingly, a plurality of charge trap spacers 312 having I-shaped structures is formed. Two opposite sidewalls of each bar structure 232 contact two of the charge trap spacers 312 respectively. The charge trap spacers 312 of the present invention can expose the upper surface of the gate conductive layer 208 of each bar structure 232 so the gate conductive layers 208 can directly couple to the subsequently formed word lines.

In other embodiments, a second silicon oxide layer (not shown) can be generally deposited on the semiconductor substrate 200, and covers the surface of the first silicon nitride layer 222. Next, a second silicon nitride layer (not shown) can be generally deposited on the semiconductor substrate 200, and covers the surface of the second silicon oxide layer. Afterward, a second etching back process is performed on the second silicon nitride layer and the second silicon oxide layer. The second etching back process can expose the gate conductive layer 208 of the bar structures 232 and parts of the semiconductor substrate 200 between the bar structures 232. A second silicon oxide layer 224 disposed on the surface of the first silicon nitride layer 222, and a second silicon nitride layer 242 disposed on the surface of the second silicon oxide layer 224 remain. Accordingly, a plurality of charge trap spacers 312 is formed.

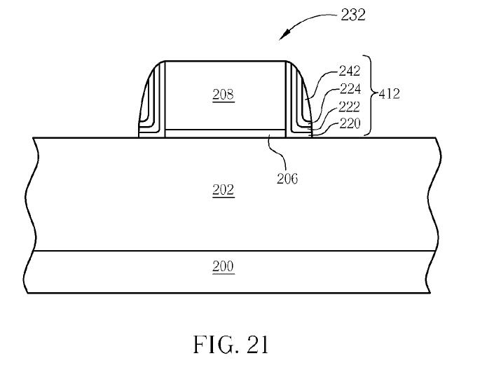

Furthermore, the charge trap spacer of the present invention can have an L-shaped structure. Please refer to FIG. 20 to FIG. 21. FIG. 20 to FIG. 21 are schematic diagrams illustrating a method of forming an SPVG SONOS memory according to the fifth preferred embodiment of the present invention, where like number numerals designate similar or the same parts, regions or elements. As shown in FIG. 20, a semiconductor substrate 200 is first provided. The semiconductor substrate 200 includes at least a P well 202 therein and a plurality of bar structures 232 thereon. Each bar structure 232 from bottom to top includes a gate dielectric layer 206 and a gate conductive layer 208. Thereafter, a first silicon oxide layer 220, a first silicon nitride layer 222, a second silicon oxide layer 224 and a second silicon nitride layer 242 are generally deposited in turn on the surface of the semiconductor substrate 200 and on the surface of the bar structures 232.

Afterward, as shown in FIG. 21, an etching back process is performed on the second silicon nitride layer 242, the second silicon oxide layer 224, the first silicon nitride layer 222 and the first silicon oxide layer 220. The etching back process can expose the gate conductive layer 208 of the bar structures 232 and parts of the semiconductor substrate 200 between the bar structures 232. Parts of the first silicon oxide layer 220, parts of the first silicon nitride layer 222, parts of the second silicon oxide layer 224 and parts of the second silicon nitride layer 242 disposed on sidewalls of the bar structures 232 remain. Accordingly, a plurality of charge trap spacers 412 having L-shaped structures is formed. Two opposite sidewalls of each bar structure 232 contact two of the charge trap spacers 412 respectively. The charge trap spacers 412 of the present invention can expose the upper surface of the gate conductive layer 208 of each bar structure 232 so the gate conductive layers 208 can directly electrically connect with the subsequently formed word lines.

According to the method for forming a memory of the present invention, a self-aligned implantation process can be performed by utilizing the bar structures and the charge trap spacers as an implantation mask to form the required N doped regions of the memory (serving as sources/drains and buried bit lines of the memory). In addition, the word lines can directly contact the select gates' surfaces in the present invention, so it is unnecessary to form additional interconnections between the select gates and the word lines. As a result, the layout area of a memory can be effectively reduced, and the manufactory process of forming the memory can be effectively simplified. Based on the memory structure of the present invention, the operation of the memory can also be simplified. Therefore, the intensity of the formed integrated circuit can be increased, and the yield and the operation efficiency of products can also be improved.

Those skilled in the art will readily observe that numerous modifications and alterations of the device and method may be made while retaining the teachings of the invention.

What is claimed is:

1. A memory having separated charge trap spacers, comprising:
a semiconductor substrate, comprising at least a first conductive type well adjacent to a surface the semiconductor substrate, and a plurality of second conductive type doped regions disposed in the first conductive type well;
a plurality of select gate structures, which do not contact each other, disposed between the second conductive type doped regions, arranged in at least one line, each of the select gate structures comprising a gate dielectric layer disposed on the first conductive type well and a gate conductive layer disposed on the gate dielectric layer;
a plurality of charge trap spacers disposed on opposite sidewalls of the select gate structures; and
a plurality of word lines, directly contacting upper surfaces of the gate conductive layers.

2. The memory of claim 1, wherein two of the charge trap spacers extend along two opposite sides of the arranged line of the select gate structures, and contact the corresponding sidewalls of each of the select gate structures respectively.

3. The memory of claim 1, wherein each of the select gate structures contacts two of the charge trap spacers, and the charge trap spacers disposed on the sidewalls of the select gate structures do not contact each other.

4. The memory of claim 1, wherein each of the charge trap spacers is an oxide-nitride-oxide (ONO) composite structure.

5. The memory of claim 1, wherein each of the charge trap spacers is an oxide-nitride-oxide-nitride (ONON) composite structure.

6. The memory of claim 1, wherein each of the charge trap spacers comprises an I-shaped structure.

7. The memory of claim 1, wherein each of the charge trap spacers comprises an L-shaped structure.

8. The memory of claim 1, wherein the second conductive type doped regions serve as a plurality of buried bit lines.

9. The memory of claim 1, further comprising an inter-gate dielectric layer, disposed outside the charge trap spacers, and covering surfaces of the second conductive type doped regions.

10. The memory of claim 1, wherein the first conductive type well is a P well, and each of the second conductive type doped regions is an N doped region.

11. A method of forming a memory having separated charge trap spacers, comprising:
providing a semiconductor substrate, the semiconductor substrate comprising at least a first conductive type well adjacent to a surface of the semiconductor substrate;
forming a plurality of bar structures, which do not contact each other, disposed on a surface of the first conductive type well, each of the bar structures comprising a gate dielectric layer disposed on the first conductive type well and a gate conductive layer disposed on the gate dielectric layer;
forming a plurality of charge trap spacers, two opposite sidewalls of each of the bar structures contacting two of the charge trap spacers respectively;
performing an implantation process by utilizing the bar structures and the charge trap spacers as a mask to form a plurality of second conductive type doped regions in the first conductive type well between the bar structures;
forming an inter-gate dielectric layer, the inter-gate dielectric layer being disposed on the second conductive type doped regions;
forming a conductive layer on the whole semiconductor substrate, the conductive layer directly contacting a surface of the gate conductive layers; and
etching the conductive layer and the bar structures so as to turn the conductive layer into a plurality of word lines, which are perpendicular to each of the second conductive type doped regions and do not contact each other, and to turn each of the bar structures into a plurality of select gate structures.

12. The method of claim 11, wherein the step of etching the conductive layer and the bar structures comprises:
forming a mask disposed on the conductive layer, the mask having a plurality of strip openings, which do not contact each other, and the strip openings being perpendicular to each of the bar structures; and
performing an etching process on the conductive layer and the bar structures by utilizing the mask as an etching mask until each of the bar structures is turned into the select gate structures.

13. The method of claim 12, wherein the etching process removes parts of the conductive layer that are not covered by the mask and parts of the bar structures that are not covered by the mask, and parts of the charge trap spacers that are not covered by the mask remain.

14. The method of claim 11, wherein the step of forming the charge trap spacers comprises:
forming a first oxide layer on the whole semiconductor substrate, covering sidewalls of the bar structures;
forming a first nitride layer on the whole semiconductor substrate, covering a surface of the first oxide layer;
etching the first nitride layer and the first oxide layer, exposing the gate conductive layer of the bar structures and parts of the semiconductor substrate between the bar structures, the first oxide layer and the first nitride layer disposed on sidewalls of the bar structures remaining; and
forming a second oxide layer, the second oxide layer covering a surface of the first nitride layer, and exposing the gate conductive layer of the bar structures and parts of the semiconductor substrate between the bar structures.

15. The method of claim 14, after forming the second oxide layer, further comprising:
forming a second nitride layer, the second nitride layer covering a surface of the second oxide layer, and exposing the gate conductive layer of the bar structures and parts of the semiconductor substrate between the bar structures.

16. The method of claim 11, wherein each of the charge trap spacers comprises an I-shaped structure.

17. The method of claim 11, wherein each of the charge trap spacers comprises an L-shaped structure.

18. The method of claim 11, wherein the step of forming the inter-gate dielectric layer comprises:
forming a dielectric layer on the whole semiconductor substrate, covering the bar structures and filling up gaps between the bar structures; and
performing a planarization process on the dielectric layer until exposing the bar structures.

19. The method of claim 11, wherein the second conductive type doped regions serve as a plurality of buried bit lines.

20. The method of claim 11, wherein the memory is a split programming virtual ground (SPVC) silicon-oxide-nitride-oxide-silicon (SONOS) memory.
